(19) United States
(12) Patent Application Publication
(10) Pub. No.: US 2007/0075775 A1
(43) Pub. Date: Apr. 5, 2007

(54) Amplifier

(76) Inventor: Xiaoyu Xi, Plano, TX (US)

Correspondence Address: TROP PRUNER & HU, PC, 1616 S. VOSS ROAD, SUITE 750, HOUSTON, TX, 77057-2631, US

(21) Appl. No.: 11/240,691

(22) Filed: Sep. 30, 2005

(51) Int. Cl. H03F 3/45

(52) U.S. Cl. 330/255

(57) ABSTRACT

An amplifier includes a first amplifier stage, a second amplifier stage and an output stage. The output stage is driven in response to a first signal and a second signal to provide an output signal. The first amplifier stage provides the first signal in response to an indication of the second signal and a first component of a differential input signal. The second amplifier stage provides the second signal in response to an indication of the first signal and a second component of the differential input signal.

### BACKGROUND

The invention generally relates to an amplifier.

An amplifier is an electronic device that typically is used for purposes of increasing the power of a signal. A voltage amplifier typically amplifies an input voltage signal to produce an output voltage signal. A transconductance amplifier converts an input current signal into an output voltage signal.

The magnitude of the input signal to the amplifier may vary over a given input voltage range, and depending on the “class” of the amplifier, certain parts of the amplifier may only be active over a certain part of this range. A “class AB” amplifier typically includes two transistors in its output stage to drive the output signal: one transistor to drive the output signal for one half of the range of the input voltage; and another transistor to drive the output voltage signal for the other half of the range. Each of these transistors remains biased on (but not necessarily in its linear region) when not driving the output signal.

A number of parameters may be used to characterize an amplifier's performance. One such parameter is the range, or available swing, of the output signal of the amplifier. An output voltage swing of an amplifier is a function of how close the output voltage signal can be to a supply rail (ground and positive supply voltage rails, as examples) without being clipped or distorted due to proximity to the rail. Another parameter that may be used to gauge performance of an amplifier is the amplifier's ability to maintain symmetry in its output signal so that, for example, the use of two different transistors to drive the output signal is not readily apparent from the output signal.

### SUMMARY

In an embodiment of the invention, an amplifier includes a first amplifier stage, a second amplifier stage and an output stage. The output stage is driven in response to a first signal and a second signal to provide an output signal. The first amplifier stage provides the first signal in response to an indication of the second signal and a first component of a differential input signal. The second amplifier stage provides the second signal in response to an indication of the first signal and a second component of the differential input signal.

In another embodiment of the invention, a technique includes amplifying a first indication of an input signal to generate a first signal to drive an output stage. A second indication of the input signal is amplified to generate a second signal to drive the output stage. The technique includes providing positive feedback to the amplification of the first component in response to the second signal and providing positive feedback to the amplification of the second component in response to the first signal.

In yet another embodiment of the invention, a wireless system includes a radio and an amplifier. The radio produces an input signal, and the amplifier amplifies the input signal to generate an output signal. The amplifier includes a first amplifier stage and a second amplifier stage. The output stage is driven in response to a first signal and a second signal. The first amplifier stage provides the first signal in response to an indication of the second signal and a first indication of the input signal. The second amplifier stage provides the second signal in response to an indication of the first signal and a second indication of the input signal.

Advantages and other features of the invention will become apparent from the following drawing, description and claims.

### BRIEF DESCRIPTION OF THE DRAWING

FIG. 1 is a block diagram of an amplifier according to an embodiment of the invention.

FIG. 2 is a more detailed schematic diagram of the amplifier according to an embodiment of the invention.

FIG. 3 is a schematic diagram of a wireless system according to an embodiment of the invention.

### DETAILED DESCRIPTION

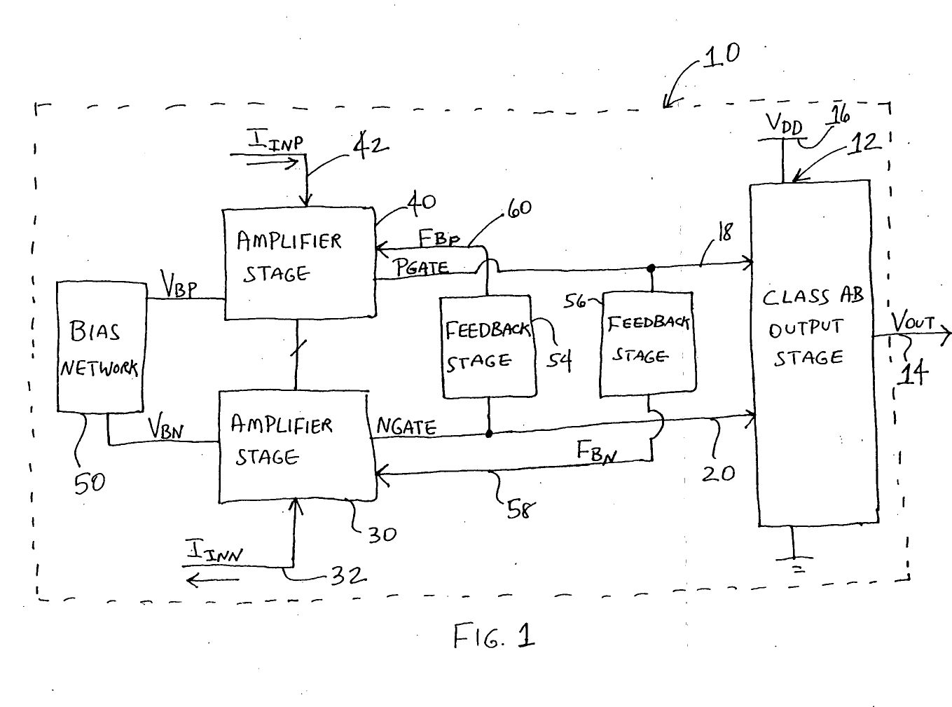

Referring to FIG. 1, an embodiment 10 of an amplifier in accordance with the invention includes a class AB output stage 12 that has complimentary output devices (described below) to generate an output voltage signal (called “V_{OUT},” in FIG. 1) at an output terminal 14 in response to an input differential current signal that is received at input terminals 32 and 42. More specifically, the input terminal 32 receives an input current signal (called “I_{INN},” in FIG. 1); and the input terminal 42 receives an input current signal (called “I_{INP},” in FIG. 1). The difference between the I_{INN} and I_{INP} input current signals forms the input differential current signal for the amplifier 10.

The I_{INN} and I_{INP} current signals remain at respective bias point current levels when the input differential current signal is considered to be “zero,” and for this input stage, the V_{OUT} output voltage signal remains at a bias point, which may be midway between a V_{DD} supply voltage (provided by a V_{DD} supply voltage rail 16) and ground, in some embodiments of the invention. The amplitude, or magnitude, of the input differential current signal may vary over a given range, which may be divided into two parts: a “high range” in which the INP input current signal is higher than its bias point, and the I_{INN} current input signal is correspondingly lower than its bias point; and a “low range” in which the I_{INP} input current signal is lower than its bias point, and the I_{INN} input current signal is higher than its bias point. One of the complementary output devices (described below) of the class AB output stage 12 drives the V_{OUT} output voltage signal in response to the input differential current signal being in its high range; and the other complementary output device (described below) of the class AB output stage 12 drives the V_{OUT} output voltage signal in response to the input differential current signal being in its low range.

As described further below, the V_{OUT} output voltage signal has a large available swing, as the amplifier 10 allows the V_{OUT} output voltage signal to come close the V_{DD} supply voltage signal and ground. Furthermore, as further described below, the design of the amplifier 10 is generally symmetric to enhance the symmetry of the V_{OUT} output voltage signal.

Turning now to the more specific details of the amplifier 10, in accordance with some embodiments of the invention, the amplifier 10 includes two amplifier stages 30 and 40 that are electrically coupled together so that depending on the magnitude of the input differential current signal, one of the stages 30 and 40 serves as an active amplifier to drive the class AB output stage 12, and the other of the stages 30 and 40 serves as the load for the active amplifier.

As a more specific example, in some embodiments of the invention, when the magnitude of the input differential current signal is in its low range, the amplifier stage 30 serves as the active amplifier to drive one of the complementary output devices of the class AB output stage 12 via a signal called “NGATE;” and the amplifier stage 40 serves as the load for the stage 30. Conversely, when the magnitude of the input differential current signal is in the high range, the amplifier stage 40 serves as the amplifier to drive the other complementary output device of the class AB output stage 12 via a signal called “PGATE;” and the amplifier stage 30 serves as its load.

Pursuant to the class AB operation, the NGATE and PGATE signals generally track each other (i.e., rise and fall together) to ensure that as the input differential current signal transitions between the high and low ranges, one of the complementary output devices of the output stage 12 turns fully on while the other complementary output device powers down. For purposes of maintaining and reinforcing this relationship between the NGATE and PGATE signals, the amplifier includes feedback stages 54 and 56.

The feedback stage 54 produces a signal (called “FBₚ” in FIG. 1) at its output terminal 60, a signal that is provided to the amplifier stage 40. The FBₚ signal serves as positive feedback (in response to the NGATE signal) to quickly drive the amplifier stage 40 into its load state when the magnitude of input differential current signal transitions from the high range into the low range, and the FBₚ signal helps drive the amplifier stage 40 into its active amplification state when the magnitude of the input differential current signal transitions from the low range into the high range.

The feedback stage 56 receives the PGATE signal and generates a signal (called “FB_{N}” in FIG. 1) on its output terminal 58. The FB_{N} signal serves as a positive feedback to the amplifier stage 30 to drive the amplifier stage 30 into its load state when the magnitude of the input differential current signal transitions from the low range into the high range, and the FB_{N} signal helps drive the amplifier stage 30 into its active amplification state when the magnitude of the input differential current signal transitions from the high range into the low range.

Among its other features, the amplifier 10 includes a bias network 50 in accordance with some embodiments of the invention. The bias network 50 provides two bias voltages: a first bias voltage (called “V_{BN},” in FIG. 1) to the amplifier stage 30 and another bias voltage (called “V_{BP},” in FIG. 1) to the amplifier stage 40.

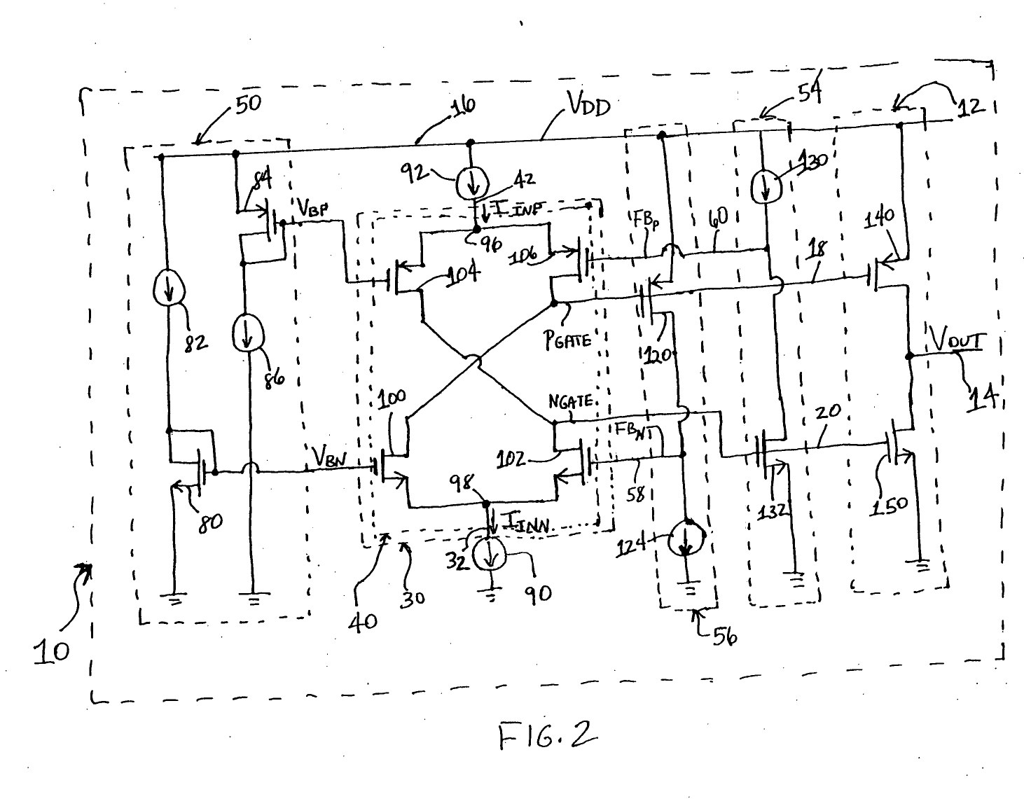

Referring to FIG. 2, in accordance with some embodiments of the invention, the amplifier stages 30 and 40 share common circuitry. In this regard, the common circuitry includes a pair of n-channel metal-oxide-semiconductor field effect transistors (NMOSFETs) 100 and 102, which have their source terminals coupled together at a node 98. The node 98 receives the I_{INN} input current signal that is, as depicted in FIG. 2, provided by a current source 90 (a current mirror that is driven by a preamplifier (not shown), for example). The gate terminal of the NMOSFET 100 receives the V_{BN} bias voltage from the bias network 50, and the gate terminal of the NMOSFET 102 receives the FB_{N} feedback signal from the feedback stage 56.

As also depicted in FIG. 2, the circuitry that is shared in common between the amplifier stages 30 and 40 also includes a pair of PMOSFET transistors: a PMOSFET transistor 104 and a PMOSFET transistor 106 that have their source terminals coupled together at a node 96. The node 96 receives the I_{INP} input current signal from a current source 92 (a current mirror that is driven by a preamplifier (not shown), for example) that is coupled to the V_{DD} supply voltage rail 16. The PMOSFET 104 receives the V_{BP} bias voltage at its gate terminal, and the gate terminal of the PMOSFET 106 receives the FBₚ feedback signal from the feedback stage 54.

As also shown in FIG. 2, the drain terminals of the NMOSFET 102 and the PMOSFET 104 are coupled together; and the drain terminals of the NMOSFET 100 and the PMOSFET 106 are coupled together.

Due to the above-described arrangement, the NMOSFETs 100 and 102 and the PMOSFETs 104 and 106 function in the following manner. In response to the magnitude of the input differential current signal being in the low range, the NMOSFETs 100 and 102 generally function as the amplification devices, and the PMOSFETs 104 and 106 function as the load for the NMOSFETs 100 and 102. More specifically, the NMOSFETs 100 and 102 function as a common gate amplifier such that the NGATE signal (provided by the drain of the NMOSFET 102) is an amplified voltage indicative of the current received at the node 98. Thus, an increase in the magnitude of the I_{INN} current signal causes the voltage of the node 98 to decrease, a decrease that causes the NMOSFET 102 to pull its drain terminal (and thus, the NGATE signal) lower. Additionally, due to a decrease in the voltage of the node 98, the NMOSFET 100 lowers the voltage of its drain terminal (and thus, lowers the PGATE voltage).

For the case in which the magnitude of the input differential current signal is in the high range, the PMOSFETs 104 and 106 serve as the active amplification devices to drive the output stage 12; and the NMOSFETs 100 and 102 function as the load to the PMOSFETs 104 and 106. In response to an increase in the magnitude of the I_{INP} current signal, the voltage of the node 96 increases, an increase that further turns on the PMOSFET 106 to cause the PMOSFET 106 to pull the PGATE signal higher. The increase in the voltage of the node 96 also causes the PMOSFET 104 to pull its drain terminal (and thus, the NGATE signal) higher.

The feedback stages 54 and 56 further reinforce the above-described action of the amplifier stages 30 and 40 due to the positive feedback that is provided by the stages 54 and 56. The feedback stage 54 includes an NMOSFET 132 that has its source terminal coupled to ground, and the gate terminal of the NMOSFET 132 receives the NGATE signal. The drain terminal of the NMOSFET 132 is coupled to the output terminal 60 of the feedback stage 56 and is coupled to one terminal of a current source 130. The other terminal of the current source 130 is coupled to the V_{DD} supply rail 16. Due to this arrangement, in response to the NGATE signal being driven low by the amplifier stage 30, the NMOSFET 132 allows the voltage of its drain terminal to rise. Thus, the FBₚ signal correspondingly rises to further turn off the PMOSFET 106. This action, in turn, causes the PMOSFET 106 to further lower the PGATE signal. It is noted that the feedback that is provided via the feedback stage 54 has an amplified effect, in that the change in the PGATE signal occurs at a faster rate than the corresponding change in the NGATE signal.

The feedback stage 56 functions in a similar manner to provide positive feedback to the NMOSFET 102. More specifically, in accordance with some embodiments of the invention, the feedback stage 56 includes a current source 124 that is coupled between the output terminal (of the feedback stage 56) and ground. The feedback stage 56 includes a PMOSFET 120 that has its source-to-drain path coupled between the V_{DD} supply voltage rail 16 and the output terminal 58. The gate terminal of the PMOSFET 120 receives the PGATE signal. Therefore, due to this arrangement, in response to the PGATE signal being driven high, this action causes the voltage of the drain terminal of the PMOSFET 120 to drop and therefore, causes a corresponding decrease in the FB_{N} signal. This decrease, in turn, further turns off the NMOSFET 102 and provides an amplified effect to allow the NGATE signal to go higher.

Among the other features of the amplifier 10, in accordance with some embodiments of the invention, the complementary output devices of the output stage 12 include a PMOSFET 140 and an NMOSFET 150. The source-to-drain path of the PMOSFET is coupled between the V_{DD} supply voltage rail 16 and the output terminal 14. The gate terminal of the PMOSFET 140 is coupled to the output terminal 18 of the amplifier stage 40 to receive the PGATE signal. The NMOSFET 150 has its drain-to-source path coupled between the output terminal 14 and ground. The gate terminal of the NMOSFET 150 is coupled to the output terminal 20 of the amplifier stage 30 to receive the NGATE signal.

The output stage 12 has a large potential voltage swing. More particularly, the V_{OUT} output voltage signal may swing to tens of millivolts within the VDD supply voltage and ground. Due to the design of the amplifier 10, the gate voltages of the two output devices 140 and 150, i.e. the PGATE and NGATE signals, may swing within two V_{DS} saturation voltages of the V_{DD} supply voltage and may also swing to within two V_{DS} saturation voltages of ground, thereby providing the maximum available gate drive to the output devices 140 and 150.

In accordance with some embodiments of the invention, the bias network 50 includes an NMOSFET 80 whose gate and drain terminals are coupled together, and the source terminal of the NMOSFET 80 is coupled to ground. A current source 82 is coupled between the V_{DD} supply voltage rail 16 and the drain terminal of the NMOSFET 80. Thus, the current source 82 and the NMOSFET 80 form a V_{GS} voltage bias circuit to provide the V_{BN} bias voltage (that appears at the gate and drain terminals of the NMOSFET 80) to the gate terminal of the NMOSFET 100. The bias network 50 includes a similar arrangement to provide the V_{BP} bias voltage to the PMOSFET 104. In this regard, the bias network 50 includes a PMOSFET 84 whose source terminal is coupled to the V_{DD} supply voltage rail 16. The gate and drain terminals of the PMOSFET 84 are coupled together, and a current source 86 is coupled between the drain terminal of the PMOSFET 84 and ground. The gate and drain terminals of the PMOSFET 84 provide the V_{BP} bias voltage.

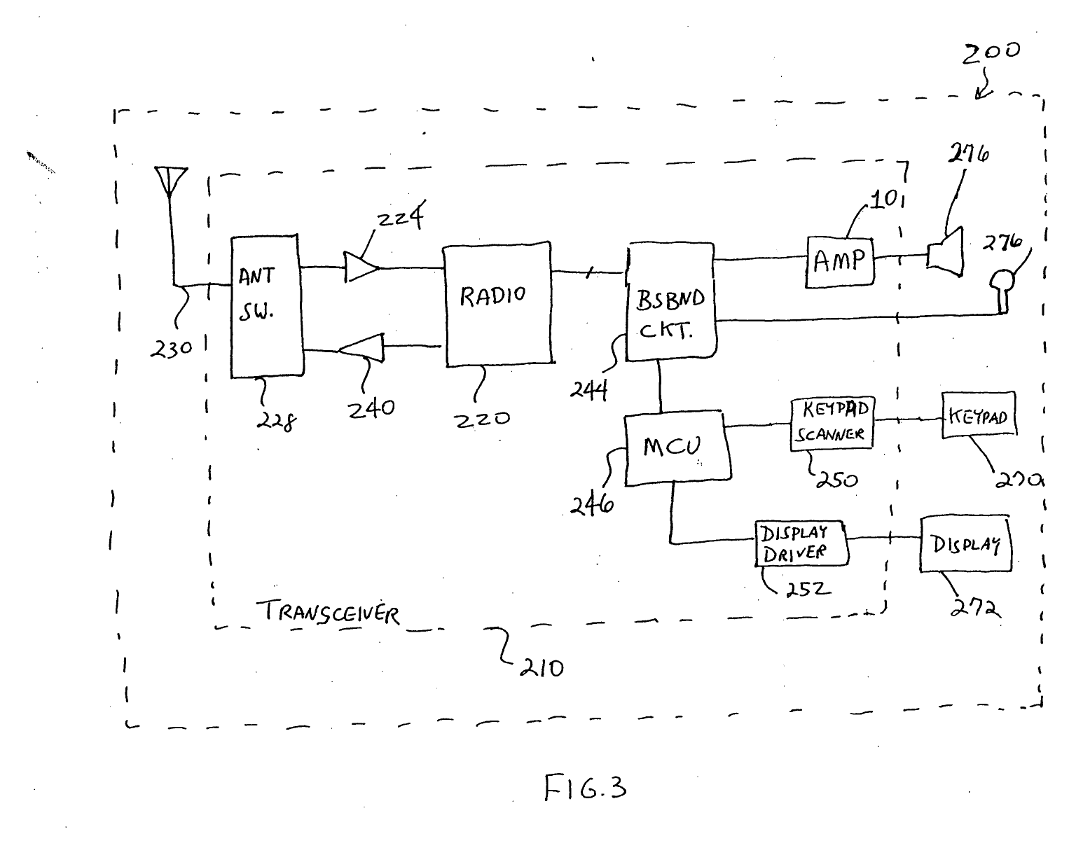

Referring to FIG. 3, the amplifier 10 may be used in a wide range of applications, depending on the particular embodiment of the invention. As a more specific example, FIG. 3 depicts a wireless system 200 that includes the amplifier 10. The wireless system 200 may be, for example, a handheld device such as a cellular telephone, or a personal digital assistant (PDA). The wireless system 200 may be a desktop or notebook computer, in some embodiments of the invention.

The wireless system 200 includes a transceiver 210 for purposes of establishing communication with a wireless network. The transceiver 210 includes a radio 220 that may, for example, provide radio frequency (RF), intermediate frequency (IF) and baseband translations for purposes of establishing communication between the wireless network and baseband circuitry 244 of the transceiver 210. Thus, the transceiver 210 may receive a wireless RF signal through an antenna 230. This received RF signal may propagate through an antenna switch 228, through a low noise amplifier 224 and to the radio 220. The radio 220 may, for example, translate the RF frequency into a baseband signal that is provided to the baseband circuitry 244 for further processing. Depending on the particular embodiment of the invention, the radio 220 may be, as examples, a dual conversion super heterodyne converter or a direct conversion radio, depending on the particular embodiment of the invention.

For transmitted signals, the radio 220 provides an RF signal to a power amplifier 240 that, in turn, communicates an amplified signal that propagates through the antenna switch 228 to the antenna 230 for transmission.

Among the other features of the wireless system 200, in accordance with some embodiments of the invention, the transceiver 210 may include, for example, a microcontroller unit (MCU) 246 that may coordinate the overall activities of the transceiver 210. The MCU 246 may be coupled to a keypad 270 via a keypad scanner 250 and may be coupled to a display 272 via a display driver 252. Depending on the particular embodiment of the invention, the transceiver 210 may be formed in a single semiconductor package. Furthermore, depending on the particular embodiment of the invention, the transceiver 210 may be formed in a single die of the semiconductor package.

Other embodiments are within the scope of the appended claims. For example, in other embodiments of the invention, the transceiver 210 may be formed on multiple dies in a single semiconductor package, and in yet other embodiments of the invention, the transceiver 210 may be formed from multiple semiconductor packages. Thus, many variations are possible and are within the scope of the appended claims.

The amplifier 10 may also be part of the transceiver 210. The amplifier 10 may receive, for example, an audio output signal from the baseband circuitry 244. The amplifier 10 amplifies the power in the received audio input signal to provide a corresponding audio output signal, an analog signal, to drive a speaker 276. As also depicted in FIG. 3, in accordance with some embodiments of the invention, the baseband circuitry 244 may receive an audio input signal via a microphone 276.

While the present invention has been described with respect to a limited number of embodiments, those skilled in the art, having the benefit of this disclosure, will appreciate numerous modifications and variations therefrom. It is intended that the appended claims cover all such modifications and variations as fall within the true spirit and scope of this present invention.

What is claimed is:

1. An amplifier comprising:
a first amplifier stage to provide a first signal in response to an indication of the second signal and a first component of a differential input signal;
a second amplifier stage to provide a second signal in response to an indication of the first signal and a second component of the differential input signal; and
an output stage to be driven in response to the first signal and the second signal to provide an output signal.

2. The amplifier of claim 1, wherein the output stage comprises:
a first transistor to provide the output signal over a first range in response to the first signal; and
a second transistor to provide the output signal over a second range in response to the second signal.

3. The amplifier of claim 1, wherein the output stage comprises a class AB output stage.

4. The amplifier of claim 1, wherein at least one of the amplifier stages comprises a common gate amplifier stage.

5. The amplifier of claim 1, further comprising:
a feedback path to provide the indication of the second signal to the first amplifier stage.

6. The amplifier of claim 5, wherein the feedback path comprises:
a transistor to provide the indication in response to the second signal; and
a current source to bias the transistor.

7. The amplifier of claim 1, wherein at least one of the indication of the first signal and the indication of the second signal comprises positive feedback with respect to the differential input signal.

8. The amplifier of claim 1, wherein the differential input signal comprises a current signal.

9. The amplifier of claim 1, wherein the first amplifier stage and the second amplifier stage have circuit components shared in common.

10. The amplifier of claim 1, wherein the first amplifier stage comprises:
a first pair of transistors comprising first current controlled paths, a first input terminal to receive the indication of the second signal and control the first current controlled paths, and a first output terminal to provide the first signal; and
a first node to receive the first component of a differential input signal and combine the first current controlled paths.

11. The amplifier of claim 10, wherein the second amplifier stage comprises:
a second pair of transistors comprising second current controlled paths, a second input terminal to receive an indication of the first signal and control the second current controlled paths, and a second output terminal to provide the second signal; and
a second node to receive a second component of the differential input signal and combine the second current controlled paths.

12. The amplifier of claim 11, wherein at least one of the first controlled current paths is coupled in series with one of the second controlled current paths.

13. The amplifier of claim 11, further comprising:
a bias network to provide a first bias voltage and a second bias voltage, wherein
the first pair of transistors further comprises a second input terminal to receive the first bias voltage, and
the second pair of transistors further comprises a second input terminal to receive the second bias voltage.

14. A method comprising:
amplifying a first indication of an input signal to generate a first signal to drive an output stage;
amplifying a second indication of the input signal to generate a second signal to drive the output stage;
providing positive feedback to the amplification of the first component in response to the second signal; and
providing positive feedback to the amplification of the second component in response to the first signal.

15. The method of claim 14, wherein
the first indication of the input signal comprises a first component of a differential input signal and the second indication of the input signal comprises a second component of the differential input signal.

16. The method of claim 14, further comprising:
driving the output stage with first signal to provide an output signal over a first range; and
driving the output signal with the second signal over a second range in response to the second signal.

17. The method of claim 14, further comprising:
tracking a bias of the first signal with a bias of the second signal.

18. The method of claim 14, wherein driving a class AB output stage with the first and second signals.

19. The method of claim 14, wherein the act of amplifying the first indication of the input signal comprises amplifying a component of a differential current signal.

20. The method of claim 14, wherein the act of amplifying the first indication of the input signal and the act of amplifying the second indication of the input signal comprises:
sharing current amplification paths between two amplifier stages.

21. A wireless system comprising:
a radio to produce an input signal; and
an amplifier to amplify the input signal to generate an output signal, the amplifier comprising:
a first amplifier stage to provide a first signal in response to an indication of the second signal and a first indication of the input signal; and
a second amplifier stage to provide a second signal in response to an indication of the first signal and a second indication of the input signal; and
an output stage to be driven in response to a first signal and a second signal to provide the output signal.

22. The wireless system of claim 21, wherein
the first indication of the input signal comprises a first component of a differential input signal and the second indication of the input signal comprises a second component of the differential input signal.

23. The wireless system of claim 21, further comprising:
a speaker to produce an audible sound in response to the output signal.

24. The wireless system of claim 21, wherein the radio comprises a radio for a cellular telephone.

25. The wireless system of claim 21, further comprising:
a handheld device containing the radio and amplifier.

26. The wireless system of claim 21, further comprising:
a semiconductor package containing the radio and the amplifier.

27. The wireless system of claim 21, further comprising:
a semiconductor die on which the radio and amplifier are fabricated.
